(19) United States
(12) Patent Application Publication
(10) Pub. No.: US 2026/0040833 A1
(43) Pub. Date: Feb. 5, 2026

(54) SEMICONDUCTOR DEVICE

(71) Applicants: National Research Council of Canada, Ottawa (CA); The University of Warwick, Coventry (GB)

(72) Inventors: Sergei STUDENIKIN, Calgary (CA); Maksym MYRONOV, Rugby (GB)

(21) Appl. No.: 19/279,435

(22) Filed: Jul. 24, 2025

(30) Foreign Application Priority Data
Aug. 1, 2024 (GB) 2411347.4

(51) Int. Cl. H10N 60/12; B82Y 10/00; H10N 60/01; H10N 60/10

(52) U.S. Cl. CPC H10N 60/12; H10N 60/01; H10N 60/11; B82Y 10/00

(57) ABSTRACT

A semiconductor device (1) is disclosed. The semiconductor device (1) comprise a substrate (2), a semiconductor structure (4) disposed on the substrate, having a principal surface (5), and comprising a semiconductor layer (10) running between first and second ends (12, 13); and a metal gate (30) disposed on the principal surface of the semiconductor structure such that a Schottky junction (31) is formed between the metal gate and the semiconductor structure, wherein the metal gate is disposed over a section (19) of the semiconductor layer between the first and second ends of the semiconductor layer for forming a channel in the semiconductor layer and controlling conduction of charge carriers between the first and second ends of the semiconductor layer.

### CROSS-REFERENCE TO RELATED APPLICATIONS

This application claims priority to United Kingdom patent application GB 2411347.4 filed Aug. 1, 2024, the entire contents of which is herein incorporated by reference.

### FIELD

The present invention relates to a semiconductor device particularly, but not exclusively, to a semiconductor device operable at cryogenic temperatures.

### BACKGROUND

Cryogenic electronics include electronic devices and systems that operate at low temperatures, typically below about 120 K, down to around 10 mK. These temperatures can be reached using liquified gases, such as nitrogen or helium, or cryogenic systems, for instance, a dilution refrigerator. The area has gained significant attention due to potential applications and uses in various sectors including quantum computing, astronomy, medical imaging, quantum sensing, telecommunications, large data centres, and artificial intelligence.

Compressively strained germanium is emerging as a versatile material platform for devices capable of encoding, processing and transmitting quantum information, and reference is made to G. Scappucci, C. Kloeffel, F. Zwanenburg, D. Loss, M. Myronov 4, J-J. Zhang, S. De Franceschi, G. Katsaros and M Veldhorst, “The germanium quantum information route”; Nature Reviews Materials, volume 6, pages 926-943 (2021). Reference is also made to M. Myronov, J. Kycia, P. Waldron, W. Jiang, P. Barrios, A. Bogan, P. Coleridge, and S. Studenikin: “Holes Outperform Electrons in Group IV Semiconductor Materials”, Small Science, volume 3, page 2200094 (2023), and M. Myronov, P. Waldron, P. Barrios, A. Bogan and S. Studenikin: “Electric field-tuneable crossing of hole Zeeman splitting and orbital gaps in compressive strained germanium semiconductor on silicon” Communications Materials, volume 4, page 104 (2023) which describes holes having a record-high mobility (4.3×10⁶ cm²V⁻¹S⁻¹) in the compressively strained germanium grown on silicon (cs-GoS).

### SUMMARY

According to a first aspect of the present invention there is provided a semiconductor device comprising a substrate and a semiconductor structure disposed on the substrate, having a principal surface, and comprising a semiconductor layer running between first and second ends. The semiconductor device comprises a metal gate disposed on the principal surface of the semiconductor structure such that a Schottky junction is formed between the metal gate and the semiconductor structure. The metal gate is disposed over a section of the semiconductor layer between the first and second ends of the semiconductor layer for forming a channel in the semiconductor layer and controlling conduction of charge carriers between the first and second ends of the semiconductor layer.

Using a Schottky gate instead of a MOS- or MIS-type gate can help to reduce or even completely avoid undesirable charges that can be collected during device operation at an interface between a gate dielectric and an underlying semiconductor which can lead to instabilities and shifts in threshold operation voltage.

The semiconductor device may further comprise a first gate structure disposed over the semiconductor structure for accumulating charge carriers in the semiconductor layer between the first end of the semiconductor layer and the section of the semiconductor layer to form a first contact region to the active channel, and a second gate structure disposed over the semiconductor structure for accumulating charge carriers in the semiconductor layer between the section of the semiconductor layer and the second end of the semiconductor layer to form a second contact region to the active channel.

This can help the semiconductor device to be better suited for operation at cryogenic temperatures and to use undoped material stack for improved performance. In particular, the first and second gate structures can be used to replace or, if present, improve doped contact regions which might otherwise deteriorate at cryogenic temperatures, for example due to carrier freezeout.

According to a second aspect of the present invention there is provided a semiconductor device comprising a substrate and a semiconductor structure disposed on the substrate, having a principal surface, and comprising a semiconductor layer running between first and second ends. The semiconductor device comprises a first gate structure disposed over the semiconductor structure for accumulating charge carriers in the semiconductor layer between the first end of the semiconductor layer and the section of the semiconductor layer to form a first contact region to a channel formed or formable in a section of the semiconductor layer between the first and second ends of the semiconductor layer, and a second gate structure disposed over the semiconductor structure for accumulating charge carriers in the semiconductor layer between the section of the semiconductor layer and the second end of the semiconductor layer to form a second contact region to the channel.

This can help the semiconductor device to be better suited for operation at cryogenic temperatures. In particular, the first and second gate structures can be used to replace or, if present, assist doped contact regions which might otherwise deteriorate at cryogenic temperatures, for example due to carrier freezeout.

The semiconductor device may further comprise a metal gate disposed on the principal surface of the semiconductor structure such that a Schottky junction is formed between the metal gate and the semiconductor structure, wherein the metal gate is disposed over a section of the semiconductor layer between the first and second ends of the semiconductor layer for forming the channel in the semiconductor layer and controlling conduction of charge carriers between the first and second ends of the semiconductor layer

The semiconductor layer may comprise, for example, consist of germanium (Ge). The semiconductor layer may be compressively-strained. Lattice mismatch in the semiconductor layer may be between 0.01% and 4%. The semiconductor layer is preferably undoped. The semiconductor layer may be doped. The semiconductor layer may have a thickness between 1 nm and 100 nm. For example, the semiconductor layer may have a thickness between 10 nm and 40 nm.

The semiconductor structure may comprise a buffer layer which is graded or not and a cap layer which provides the principal surface, and the semiconductor layer is interposed between the buffer layer and the cap layer.

The buffer layer may comprise, for example, consist of Si₁₋ₓGeₓ, wherein x changes from x₁ (at the bottom of the layer) to x₂ (at the top of the layer), for example where x₁>x₂, and the cap layer may comprise, for example, consist of Si_{1-z}Ge_{z}. In some cases, x₂=y. In other cases, x₂>y or x₂<y. The buffer layer may terminate with a germanium content, x₂, between 0.2 and 0.95. The buffer layer may have a thickness between 0.05 and 10 μm. The cap layer may have a germanium content, z, of between 0.2 and 0.95.

The semiconductor structure may further comprise a relaxed layer interposed between the buffer layer and the semiconductor layer. The relaxed layer may comprise, for example, consist of Si_{1-y}Ge_{y}. The relaxed layer may have a thickness between 0.05 and 10 μm. The relaxed layer may have a germanium content, y, of between 0.2 and 0.95.

The semiconductor layer may provide the principal surface. In other words, the semiconductor device need not have a cap layer and/or the semiconductor layer need not be buried.

The metal gate may comprise, for example, consist of titanium (Ti) or tungsten (W), or can consist of Ti and gold (Au).

The first gate structure may comprise a gate dielectric layer and a gate electrode layer, and the gate dielectric layer may be interposed between the semiconductor structure and the electrode layer. The second gate structure may comprise a gate dielectric layer and a gate electrode layer, and the gate dielectric layer may be interposed between the semiconductor structure and the electrode layer. The first and second gate structure may comprise a gate dielectric layer and a gate electrode layer,
and the gate dielectric layer is interposed between the semiconductor structure and the electrode layer.

The substrate may comprise, for example consist of silicon (Si). The substrate may be a Si (001), Si(110) or Si(111) substrate.

According to a third embodiment of the present invention there is provided an integrated circuit comprising at least one device of the first or second aspect of the present invention.

According to a fourth embodiment of the present invention there is provided a quantum information processing circuit comprising at least one device of the first or second aspect of the present invention.

### BRIEF DESCRIPTION OF THE DRAWINGS

Certain embodiments of the present invention will now be described, by way of example, with reference to the accompanying drawings, in which:

FIG. 1 is a schematic cross-sectional view of a semiconductor device;

FIG. 2 is a micrograph of a semiconductor device in the form of a Hall bar;

FIGS. 3A to 3D are plan views of the semiconductor device shown in FIG. 2 at different stages during fabrication;

FIG. 4 is a plot of source-drain current against gate voltage for source and drain accumulation gate voltages when a voltage of −100 mV is applied to a Schottky gate for the Hall bar shown in FIG. 2 measured at 4.2 K;

FIG. 5 is a plot of Schottky gate leakage current against Schottky gate voltage in the forward-bias direction for the Hall bar shown in FIG. 2 measured at 4.2 K;

FIG. 6 is a plot of hole mobility of free carriers as a function of the Schottky gate voltage in the Hall bar shown in FIG. 2 measured at T=4.2K;

FIG. 7 is a plot of mean free path of free carriers as a function of the Schottky gate voltage in forward bias direction, in other words, in the enhancement mode for the Hall bar shown in FIG. 2 measured at 4.2 K;

FIG. 8 is a 2D greyscale map of enhancement mode source-drain current as a function of Schottky gate voltage and source-drain voltage for the Hall bar shown in FIG. 2 measured at 4.2K;

FIG. 9 is a plot of source-drain current as a function of source-drain voltage for gate voltages in a range between −10 mV to −28 mV in 2 mV steps for the Hall bar shown in FIG. 2 measured at 4.2 K;

FIG. 10 is a logarithmic plot of source-drain current as a function of Schottky gate voltage for the Hall bar shown in FIG. 2 measured at 4.2 K;

FIG. 11 is a linear plot of source-drain current as a function of Schottky gate voltage for the Hall bar shown in FIG. 2 measured at 4.2 K;

FIG. 12 is a plan view of a semiconductor device in the form of a field-effect transistor;

FIG. 13 is a cross-section view of the field-effect transistor shown in FIG. 12;

FIGS. 14A to 14F are plan views of the field-effect transistor shown in FIG. 12 at different stages during fabrication;

FIGS. 15A to 15F are cross-sectional views of the field-effect transistor shown in FIG. 12 at different stages during fabrication;

FIG. 16 is a process flow diagram of a method of fabricating the device shown in FIG. 12;

FIG. 17 is a plan view of semiconductor device in the form of a double quantum dot qubit device;

FIG. 18 is a schematic cross-sectional view of the semiconductor device shown in FIG. 17 taken along the line B-B′; and

FIG. 19 is a schematic cross-sectional view of the semiconductor device shown in FIG. 17 taken along the line C-C′.

### DETAILED DESCRIPTION OF CERTAIN EMBODIMENTS

In the following, like parts are denoted with like reference numerals.

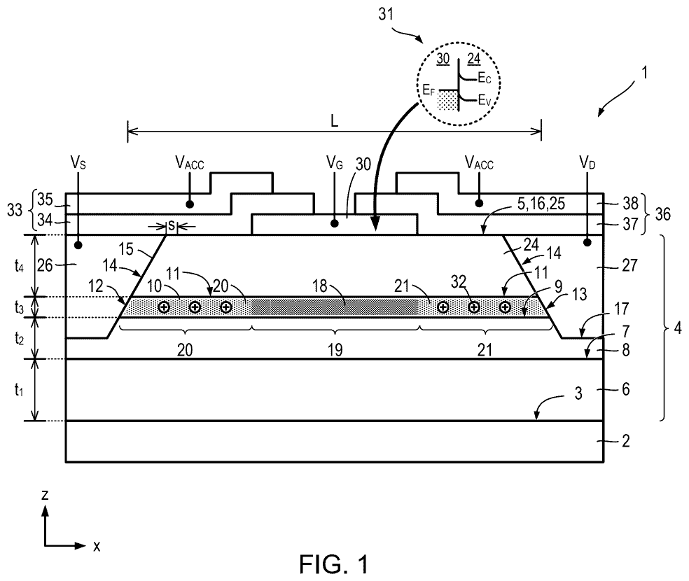

Referring to FIG. 1, a semiconductor device 1 in the form of a field-effect transistor is shown.

The device 1 comprises a substrate 2, in the form of a (001) orientated silicon substrate having an upper surface 3 (or “top”). A semiconductor structure 4 is disposed on the upper surface 3 of the substrate 2 and has a principal surface 5.

The semiconductor structure 4 takes the form of a undoped, compressively-strained (cs) germanium-on-silicon (GoS) stack.

A graded buffer layer 6, in the form of a layer of undoped linearly-graded silicon germanium/germanium (Si₁₋ₓGeₓ/Ge), is disposed directly on the substrate 2 and has an upper surface 7. In this example, the graded buffer layer 6 terminates at a composition of Si_{0.15}Ge_{0.85} and has a first thickness, t₁, of 2 μm.

A relaxed buffer layer 8, in the form of a layer of undoped Si_{1-y}Ge_{y}, is disposed on the buffer graded buffer layer 6 and has an upper surface 9. In this example, the relaxed buffer layer 8 takes the form of Si_{0.15}Ge_{0.85} and has a second thickness, t₂, of 100 nm.

A semiconductor layer 10, in the form of a compressively-strained layer of undoped germanium, is disposed on the relaxed buffer layer 8 and had an upper surface 11. The semiconductor layer 10 runs between first and second ends 12, 13 defined by side walls 14 of a mesa 15. The mesa 15 has a top (unetched) surface 16 and is surrounded by a bottom (etched) surface 17. In this example, semiconductor layer 10 takes the form of undoped Ge, and has a third thickness, t₃, of 30 nm.

As will be explained in more detail later, the semiconductor layer 10 forms a quantum well and an active region 18 (or “conducting channel” or simply “channel”) is formable in a section 19 of the semiconductor layer 10, and first and second contact regions 20, 21 are formable either side of the active region 18 in respective first and second sections 22, 23 of the semiconductor layer 10.

A cap layer 24, in the form of a layer of undoped Si_{1-z}Ge_{z}, is disposed on the semiconductor layer 10 and has an upper surface 25, corresponding to the top of the mesa 15 and providing the principal surface 5 of the semiconductor structure 4. In this example, the cap layer 24 takes the form of Si_{0.15}Ge_{0.85} and has a fourth thickness, t₄, of 100 nm.

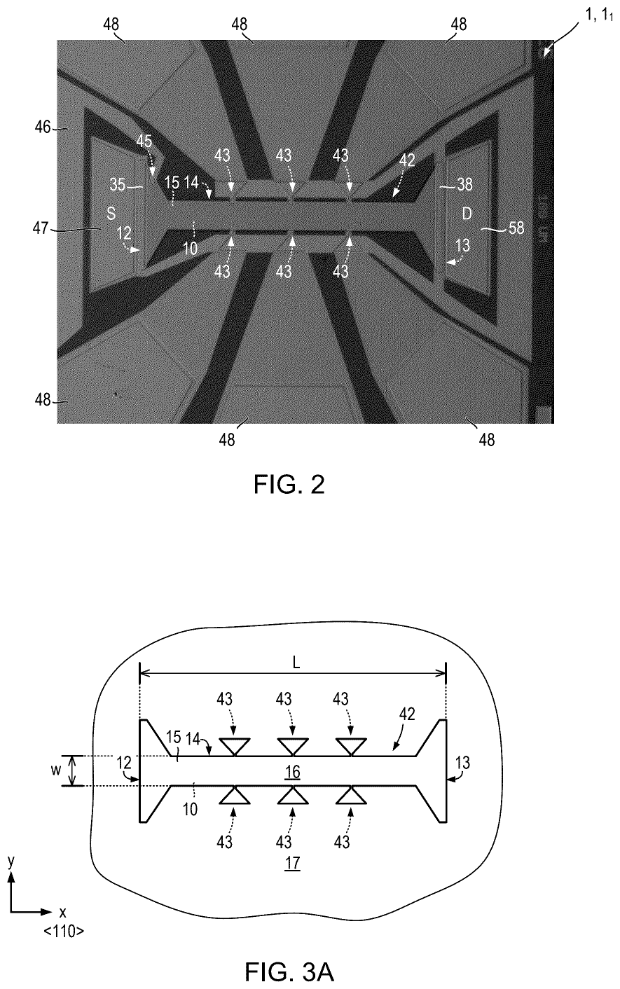

First and second contacts 26, 27 (herein also referred to as “source and drain contacts”) are respectively disposed at the first and second ends 12, 13 of the semiconductor layer 10. The first and second contacts 26, 27 comprise, for example, aluminium (Al) or other suitable metallization and interfacial regions 28, 29 (FIG. 2B). The contacts 26, 27 are formed on the etched bottom surface 16 defining the mesa 15. In this case, the bottom surface 16 lies within the relaxed buffer layer 8. The contacts 26, 27 run from the etched bottom surface 16 and up the sidewalls 14 of the mesa 15. Although not illustrated for clarity, the contacts 26, 27 also extend a short distance, s, onto the top of the mesa 15, in other words, onto the cap layer 24.

A metal gate 30 is disposed on the principal surface 5 of the semiconductor structure 4 such that a Schottky junction 31 is formed between the metal gate 30 and the semiconductor structure 4, in particular, the cap layer 24. The metal gate 30 is herein also referred to as a “Schottky gate”. The Schottky gate 30 is disposed over a section 19 of the semiconductor layer 10 between the first and second ends 12, 13 of the semiconductor layer 10. In response to a suitable gate bias, V_{G}, the Schottky gate 30 forms an active region 18 (or “channel”) in the semiconductor layer 10, and can be used to control conduction of charge carriers 32, in this case holes, between the first and second ends 12, 13 of the semiconductor layer 10.

A first gate structure 33 (herein also referred to as the “first accumulation gate structure”) comprising a gate dielectric 34 and a gate metallization 35 (or “accumulation gate”) is disposed over the semiconductor structure 4 for accumulating charge carriers 32 in the semiconductor layer 10 between the first end 12 of the semiconductor layer 10 and the section 19 of the semiconductor layer 10, that is in a first section 22 of the layer 10, to form a first contact region 20 to the channel 18. A second gate structure 36 (herein also referred to as the “second accumulation gate structure”) comprising a gate dielectric 37 and a gate metallization 38 (“accumulation gate”) is disposed over the semiconductor structure 4 for accumulating charge carriers 32 in the semiconductor layer 10 between the section 19 of the semiconductor layer and the second end 13 of the semiconductor layer, that is in a second section 23 of the layer 10, to form a second contact region 21 to the channel 18.

Although shown as separate structures in FIG. 1, the first and second accumulation gates 35, 38 can be different areas of the same metallization. The structure may be patterned or may be unpatterned (for example, a globally formed pad for a device).

If the first and second accumulation gates 35, 38 are separate and not electrically connected, then the same or different gate voltages may be applied to the first and second accumulation gates 35, 38.

### Hall Bar Device

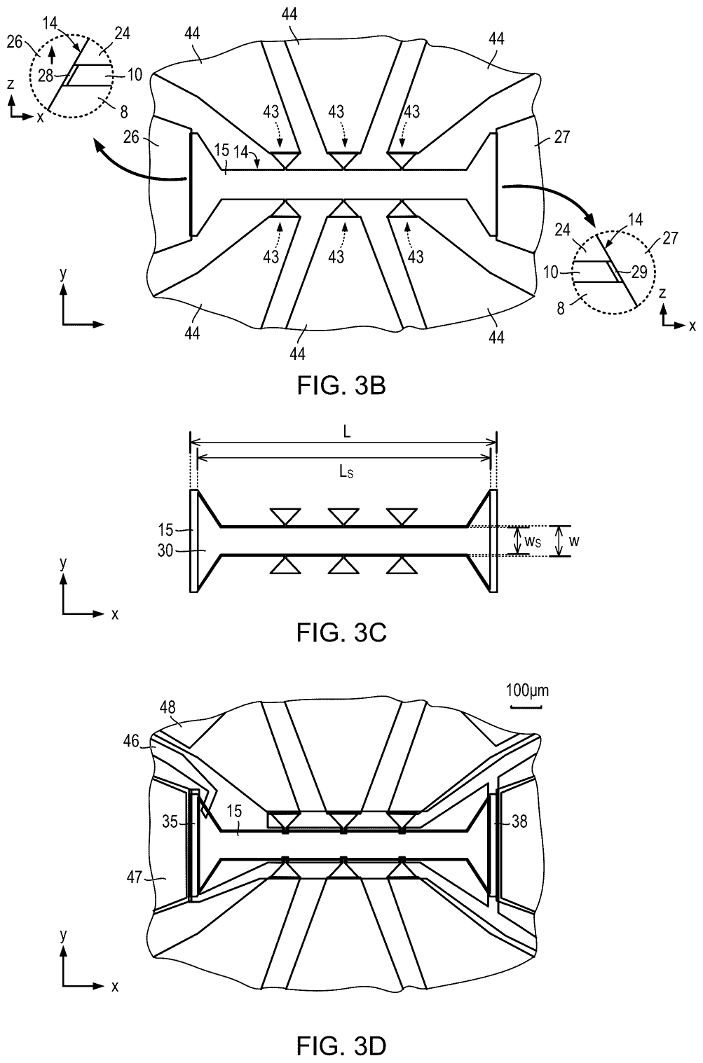

Referring to FIGS. 2 and FIGS. 3A to 3D, in a first example, the semiconductor device 1, 11 is shown which takes the form of a double-gated Hall bar 42, which is also operable as a field-effect transistor. The semiconductor device 1, 11 is also herein referred to as a “Cryo-FET”. The semiconductor device 1, 11 is fabricated using UV lithography, dry etching and thin film deposition processes

FIG. 2 is an optical micrograph of the semiconductor device 1, 11. FIGS. 3A to 3D illustrate the device 1, 11 during different stages of fabrication and can be used to help identify different parts of device shown in FIG. 2A including the mesa 15 and a set of Hall probes 43 which define the extent of the semiconductor layer 10 (FIG. 1), the source and drain contacts 26, 27 (FIG. 1), the Schottky gate 30 (FIG. 1), and the accumulation gates 35, 38 (FIG. 1) which are provided by different areas of the same gate metallization.

Referring in particular to FIG. 2 and FIG. 3A, the Hall bar 42 is orientated along the <110> in-plane crystallographic direction and is defined by the mesa structure 15. The Hall bar 42 is formed by etching an heterostructure (not shown) through a resist mask (not shown) using a chlorine/argon (Cl₂/Ar) plasma. The width, w, of the Hall bar 42 is 100 μm and the length, L, between source and drain contacts 26, 27 (FIG. 2C) is 1,000 μm.

The heterostructure is grown by reduced pressure chemical vapor deposition (RP-CVD) on a Si(001) wafer having a diameter of 150 mm. Further details regarding material growth can be found in “Holes Outperform Electrons in Group IV Semiconductor Materials” ibid. and in C. Morrison and M. Myronov, “Electronic transport anisotropy of 2D carriers in biaxial compressive strained germanium”, Applied Physics Letters, volume 111, page 192103 (2017) which are incorporated herein by reference.

The undoped cs-GoS material stack 4 is naturally non-conductive at cryogenic temperatures. The accumulation gates 35, 38 (FIG. 1), however, can be used to create mobile carriers 32 (FIG. 1) in the contact regions 20, 21 (FIG. 1), adjacent to the channel 18 (FIG. 1), which in this case is a p-channel.

The semiconductor device 1 does not have doped contact regions formed, for example, by ion implantation. A semiconductor device 1 may, however, have doped contact regions.

Referring in particular to FIG. 2 and FIG. 3B, the source and drain contacts 26, 27 include, for example, alloyed AlSiGe ohmic contact regions 28, 29 (or simply “ohmic contacts”). The contacts can be made from another materials, for example, platinum (Pt). The source and drain contacts 26, 27 are formed by evaporating a layer of aluminium (Al), in this case having a thickness of 120 nm, over end sidewalls 14 of the Hall bar 42 and annealing the aluminium layer at about 275° C. in nitrogen (N₂) gas ambient for 30 minutes.

When the device is operating in enhancement mode, the ohmic contacts 28, 29 exhibit low resistivity and excellent linear ohmic behaviour at cryogenic temperatures.

During this step, a set of contacts 44 to the Hall probes 43 are also formed.

Referring in particular to FIG. 2 and FIG. 3C, the Schottky gate 30 is formed on top of the mesa 15. The Schottky gate 30 takes the form of bilayer comprising a layer of titanium (Ti) having a thickness of 20 nm and a covering layer of gold (Au) having a thickness of 200 nm. The Schottky gate 30 has a length, L_{S}, which is less than the length of the mesa 15, in this case, about 950 μm, and has a width, w_{S}, which is less than the width of the mesa 15, in this case, about 95 μm.

A layer of dielectric in the form of form of a layer of aluminium oxide (Al₂O₃) having a thickness of 50 nm deposited by Atomic Layer Deposition (ALD) at 200° C.

A via 45 in the dielectric layer is opened by dry etching to allow electric contact to the underlying gate 30. Vias can also be opened to source and drain contacts 26, 27 and the Hall probe contacts 44.

Referring to FIG. 2 and FIG. 3D, the accumulation gates 35, 38 are formed over the ends of Schottky gates 30 and the ends of the mesa 15. The accumulation gates 35, 38 also run over the Hall probes 43.

During this step, a contact 46 to the Schottky gate 30 and contacts 47, 48 to the source and drain contacts 26, 27 and contacts 49 to the Hall probe contacts 44 are also formed.

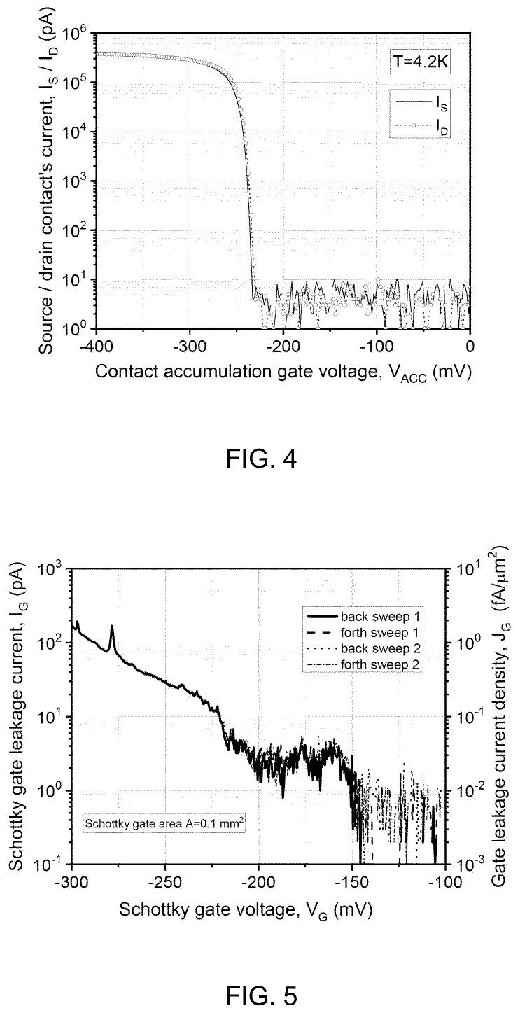

FIG. 4 shows voltage-activation characteristics of the source and drain measuring current though contacts 26, 27 (FIG. 3B) individually, with all other contacts being grounded.

Superior reproducibility of contacts is evident from FIG. 4 with a threshold at an accumulation voltage V_{ACC}=−230 mV, which depends on thickness of the dielectric layer. In the following, further measurements of device characteristics are performed at V_{ACC}=−350 mV. Other accumulation voltages V_{ACC}, however, can be used for operation.

### Electrical Characterization

Referring again to FIG. 2, the Cryo-FET 1, 1₁ takes the form of a bar called a Hall bar and has potential probes 43 which allows intrinsic material properties, such as free-carrier mobility, carrier density and mean free path, to be measured. These parameters can be used to understand operation of the devices. The Cryo-FET 1, 1₁ is also operated in FET mode to measure its input and output characteristics. Electrical performance of the Cryo-FET device was carried out at temperature of 4.2 K.

The Schottky gate 30, compared to gate in MIS-type transistors, can help to reduce and even completely avoid the effect of undesirable charges at the interface of a semiconductor and a dielectric, which can lead to instabilities and to shifts in threshold, and voltage shifts in characteristics of gated devices.

Referring FIG. 5, an I-V characteristic of Schottky gate current, IG, versus Schottky gate voltage, V_{G}, in a forward direction is shown. The minimum leakage current is below the detectable limit of the experimental measurement setup. Some small leakage current appears at Schottky gate voltage, V_{G}, below −150 mV, within a few picoamperes, and starts growing exponentially for voltages below −220 mV, following expected Schottky contact behaviour in enhancement mode. It should be noted that this is an extremely low value for a relatively large area of 0.1 mm² of the device.

Referring still to FIG. 5, reproduceable sharp peaks are observed for four back-and-forth sweeps. Without wishing to be bound by theory, this may be due to resonant tunnelling through deep level states.

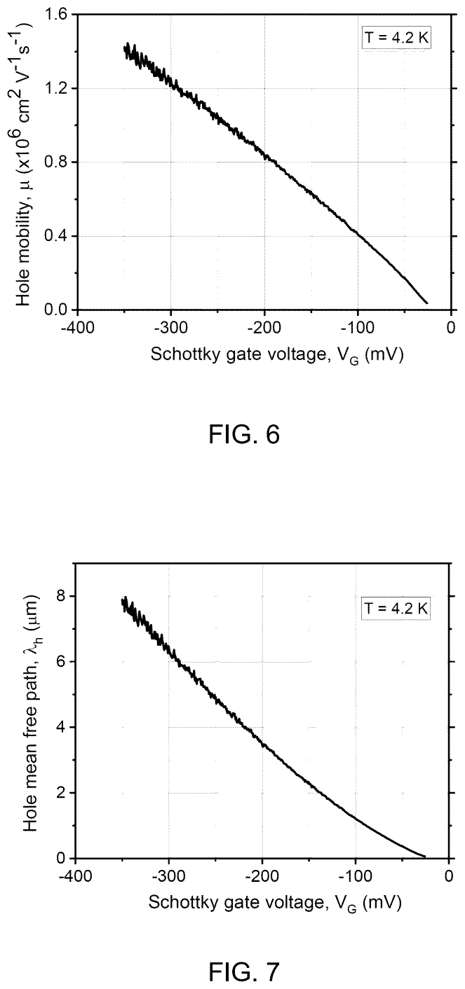

Referring to FIG. 6, a very high hole mobility of 1.5×10⁶ cm²V⁻¹S⁻¹ is measured at a Schottky gate voltage, V_{G}=−350 mV.

Referring also to FIG. 7, as a consequence, hole mean free path reaches 8 μm. This indicates that the Cryo-FET device 1, 1₁ having a gate length below this value, that is below 8 μm, will operate in a ballistic regime, which may lead to even lower heat dissipation.

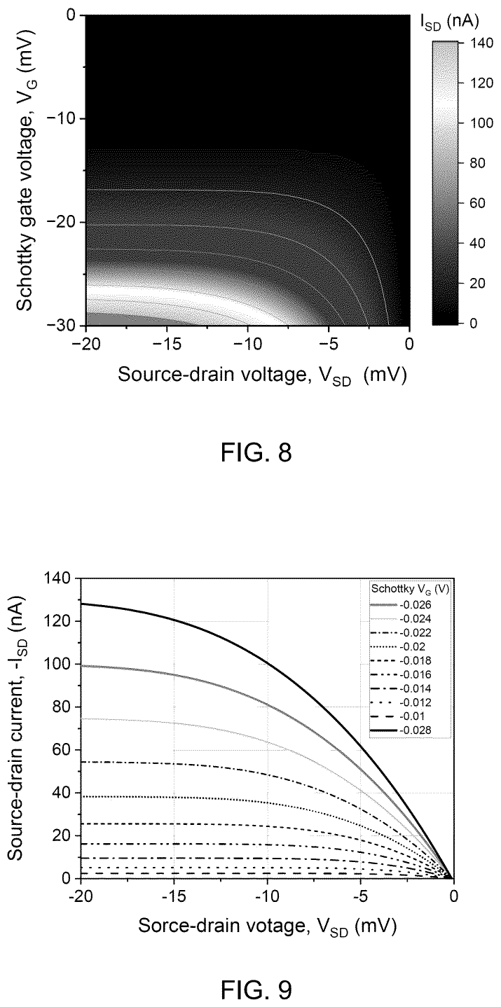

Referring to FIG. 8, a 2D grayscale plot of typical input characteristics of the cryo-FET is shown.

Referring to FIG. 9, plots of source-drain current, I_{SD}, against source-drain voltage, V_{SD}, at different Schottky gate voltage, V_{G}, are shown. Due to a high mobility, source-drain current, I_{SD}, saturates quickly at low source-drain voltage, V_{SD}, namely around −10 mV.

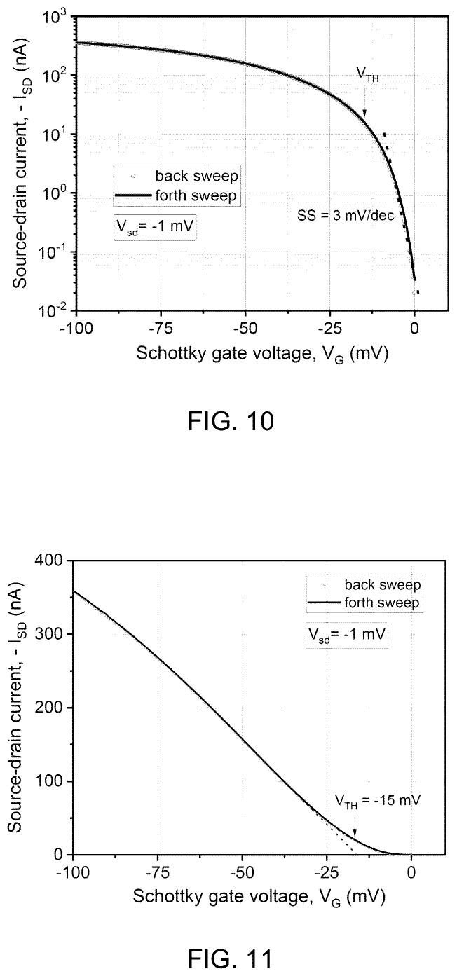

Referring to FIGS. 10 and 11, hysteresis plots of source-drain current, I_{SD} against Schottky gate voltage, V_{G}, on semi-logarithmic scale and linear scales are shown.

These results show superior performance of the Cryo-FET 1, 1₁. For example, no any noticeable hysteresis is observed, there is low Schottky gate threshold voltage, V_{TH}=−15 mV, and there is a very low sub-threshold swing (SS) of about 3 mV/dec. The Cryo-FET 1, 1₁ reveals reliable gate control with undetectable minimum leakage currents. The off current of the FET is below 1 pA, which is limited by the cryogenic measurements experimental setup including electronics, circuits, cables and wiring. It should be noted that no temperature rise was observed during the measurements indicating an ultra-low power dissipation of the Cryo-FET device.

A comparative analysis was conducted between the Cryo-FET 1, 1₁ and FETs based on conventional semiconductor materials described in G. Kiene et al., “A 1-GS/s 6-8-b Cryo-CMOS SAR ADC for Quantum Computing,” IEEE Journal of Solid-State Circuits, pp. 1-12 (2023) and X. Xue et al., “CMOS-based cryogenic control of silicon quantum circuits,” Nature, vol. 593, no. 7858, pp. 205-210 (2021).

The Cryo-FET 1, 1₁ shows superior performance thanks to the very high hole mobility and material design and stack quality and resulted in very low sub-threshold swing, very low Schottky gate leakage current in the enhancement mode, very low Schottky gate threshold voltage, V_{TH}, the absence of any hysteretic behaviour, and superior stability of all FET characteristics at cryogenic temperatures. The Cryo-FET characteristics were repeatedly obtained during several days and no measurable drift of any characteristic was observed. Based on the very high carrier mobility, it is estimated that the Cryo-FET 1, 1₁ can operate in a very low dissipation power regime, with estimated ˜50 pW of Joule heat dissipation. This means that an ULSI circuit containing, for example, one million of such transistors would dissipate just ˜50 μW of heat power which is within the cooling power capability of modern cryogenic-free dilution refrigerators operating down to <100 mK.

Thus, the heterostructure and the device offer benefits as a platform for cryogenic electronic applications, and open up possibilities for use in cryogenic classical and quantum electronic systems. Applications include, among others, low-power quantum computing circuits, cryogenic sensors, deep space electronics, data centres, and artificial intelligence. The high mobility and ultra-low power consumption of semiconductor devices 1 are particularly beneficial for high-speed cryogenic electronics where energy efficiency and performance are critical.

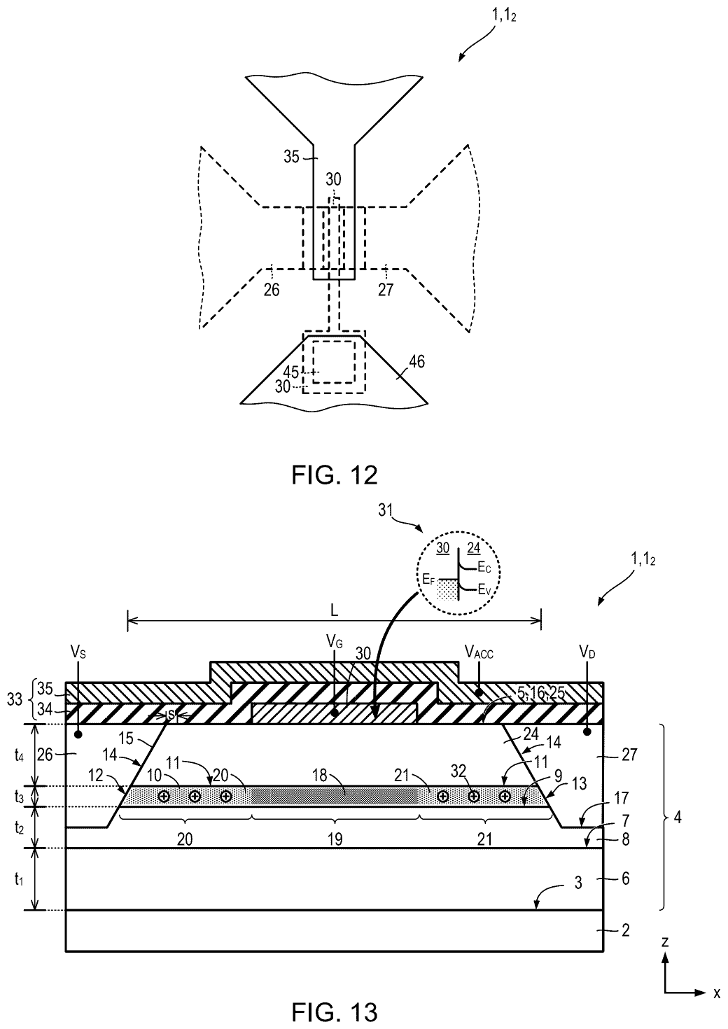

Referring to FIGS. 12 and 13, a second example of a semiconductor device 1, 1₂ is shown. The second semiconductor device 1, 1₂ is similar to the first semiconductor device 1, 1₁ except that it is configured to be used as an FET and, thus, does not have Hall probes, has a smaller mesa, and has a shorter gate length.

Referring in particular to FIG. 13, a single accumulation gate structure 33 is used which covers the Schottky gate 30 and the exposed surface 16 of the mesa 15. Again, for clarity, the contacts 26, 27 are not shown as extending onto the top of the mesa 15.

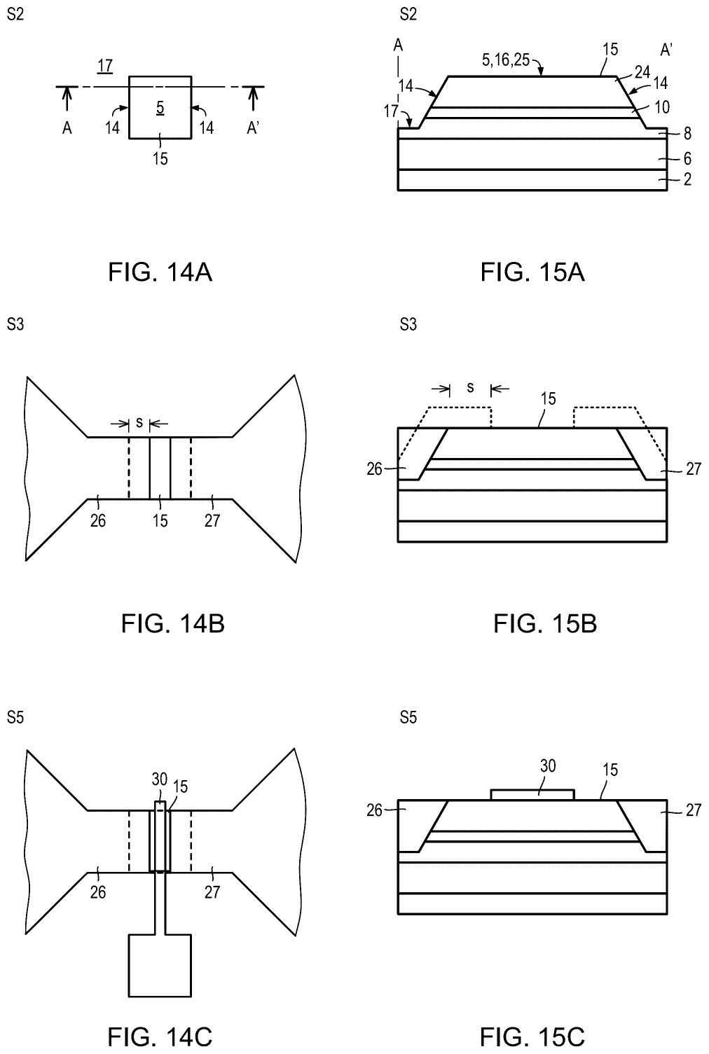

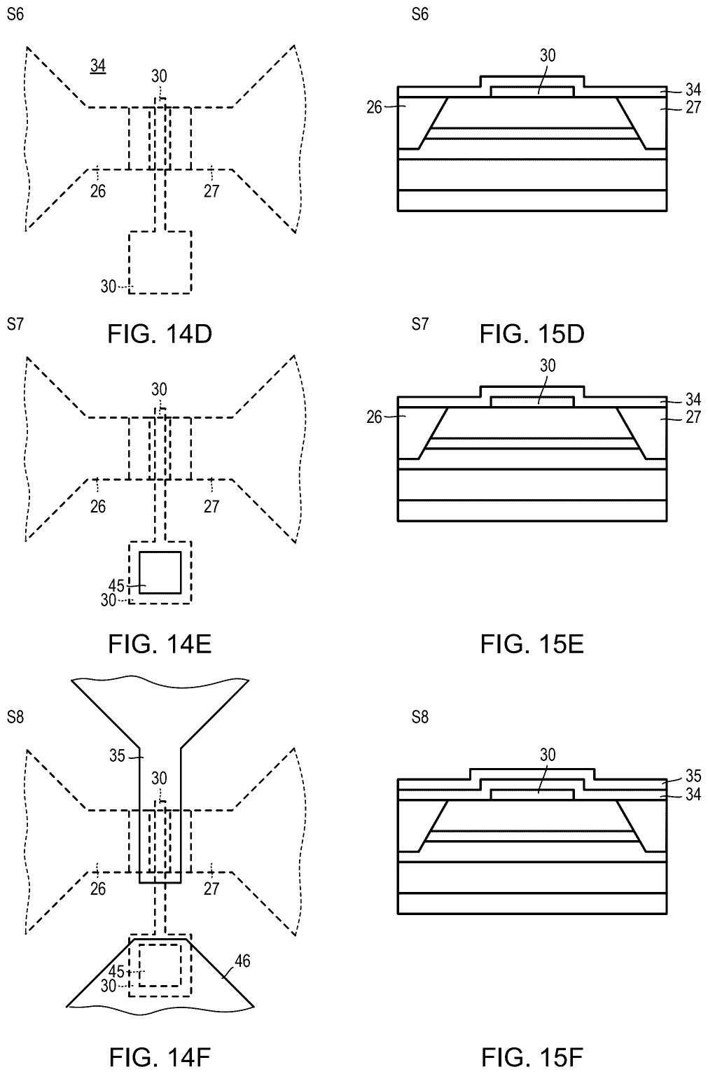

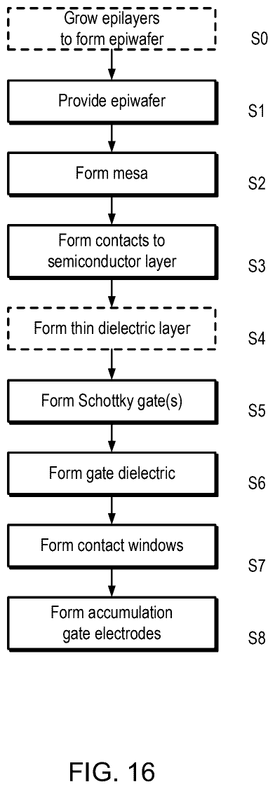

Referring to FIGS. 14A to 14F, FIGS. 15A to 15F, and FIG. 16, a method of fabricating the semiconductor device 1, 1₂ will now be described.

The epiwafer is formed by growing a stack of layer, for example, by RP-CVD (step S0) or obtained commercially, for example, from the University of Warwick (step S1). Further details regarding material growth can be found in “Holes Outperform Electrons in Group IV Semiconductor Materials” ibid. and “Electronic transport anisotropy of 2D carriers in biaxial compressive strained germanium ibid.

Referring in particular to FIGS. 14A, 15A and 16, a mesa 15 is formed using a resist mask (not shown) and then etching using a chlorine/argon (Cl₂/Ar) plasma (step S2).

Referring in particular to FIGS. 14B, 15B and 16, the source and drain contacts 26, 27 are formed by evaporating a thin film of aluminium (not shown) over the sidewalls 14, mesa 15, and etched surface 17, patterning the thin film using a resist mask (not shown) and dry-etching using a chlorine-based etch, and then annealing the patterned aluminium layer (step S3).

FIG. 15B shows, in chain, the contacts 26, 27 extending onto the top of the mesa 15. In the following FIGS. 15C to 15F, however, the contacts 26, 27 are not shown as extending onto the top of the mesa 15.

Optionally, a dielectric layer, for example in the form of silicon dioxide, may be deposited over the source and drain contacts 26, 27, the mesa 15, and the etched surface 17 using a CVD process (step S4).

Referring in particular to FIGS. 14C, 15C and 16, the Schottky gate 30 is formed on top of the mesa 15 by evaporating a layer of titanium (Ti) then a layer of gold (Au) and patterning the bi-layer using a resist mask (not shown) and dry-etching (step S5).

Referring in particular to FIGS. 14D, 15D and 16, a dielectric layer 34 in the form of aluminium oxide (Al₂O₃) is deposited over the Schottky gate 30, the source and drain contacts 26, 27, the exposed areas of the mesa 15, and the etched surface 17 using a dry or wet etch process (step S6).

Referring in particular to FIGS. 14E, 15E and 16, a via 45 is opened in the dielectric layer 34 allow electrical contact to be made to the Schottky gate 30 and to the source and drain contacts 26, 27 by patterning the dielectric layer 34 using a resist mask (not shown) and dry-etching the exposed region of the dielectric layer 34 using an RIE process (step S7). The vias to the source and drain contacts 26, 27 are made further away from the mesa 15 and so are not shown in FIGS. 14E and 15E.

Referring in particular to FIGS. 14F, 15F and 16, the accumulation gate 35 and contact metallization to the Schottky gate 30 and to the source and drain contacts 26, 27 are formed over the ends of Schottky gates 30 by evaporating a layer of titanium (Ti) then a layer of gold (Au) and patterning the bi-layer using a resist mask (not shown) and dry-etching (step S8).

### Quantum Dot Qubit Device

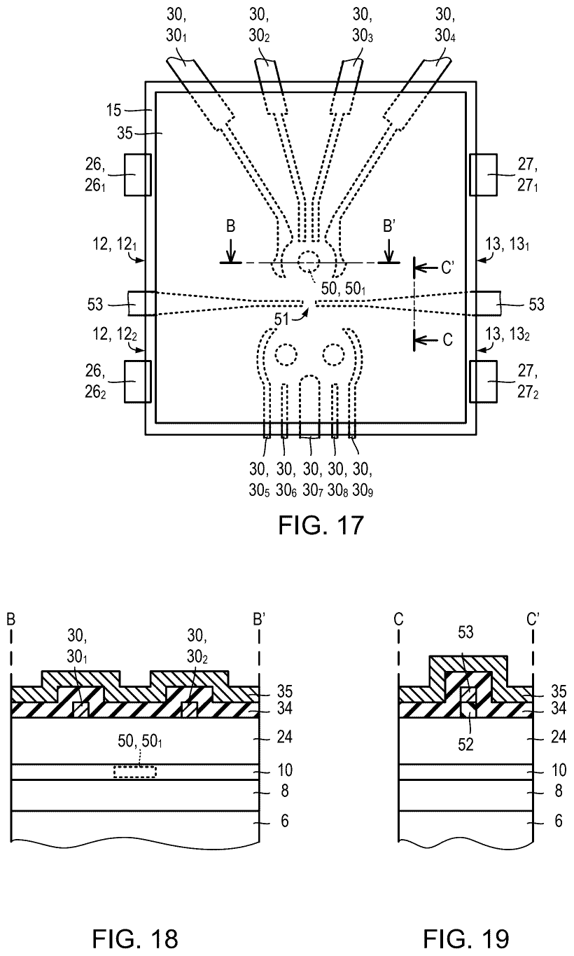

Referring to FIG. 17, a third example of a semiconductor device 1, 1₃ is shown. The semiconductor device 1, 1₃ is fabricated using the same material stack (with the same undoped cs-GoS material layer structure) as hereinbefore described, and so will not be described again here.

The semiconductor device 1, 1₃ comprises a mesa 15 on which are formed a plurality surface gates in the form of Schottky gates 30, 30₁, 30₂, . . . ,30₉. In some examples, the surface gates are field-effect gates separated from the mesa 15 by a thin dielectric layer. The surface gates 30, 30₁, 30₂, . . . , 30₉ are arranged to form, control and manipulate a first quantum dot 50, 50₁ and second and third quantum dots 50, 50₂, 50₃ in the semiconductor layer 10 for providing respective spin qubits.

The use of a Schottky gate, accumulation gate(s) and undoped semiconductor material can help the qubit device to operate reproducibly and more stably. The first quantum dot 50, 501 and the double dot 50, 50₂, 50₃ are separated by a surface split gate 51 comprising a dielectric layer 52 and a gate electrode 53. The split gate can be used to isolate the first quantum dot 50, 50₁ and double dot 50, 50₂, 50₃.

Several contacts 26, 26₁, 26₂, 27, 27₁, 27₂ are made to the semiconductor layer 10 in the same way as described earlier. The contacts 26, 27 can be used to supply carriers to the first quantum dots 50, 50₁, 50₂, 50₃ and to perform qubit operations and readout using electronic transport methods.

A global accumulation gate 35 is used to generate carriers and to control their density in the germanium layer 10 of the undoped GoS material stack 4.

It will be appreciated that various modifications may be made to the embodiments hereinbefore described. Such modifications may involve equivalent and other features which are already known in the design, manufacture and use of semiconductor devices component parts thereof and which may be used instead of or in addition to features already described herein. Features of one embodiment may be replaced or supplemented by features of another embodiment.

The semiconductor layer may comprise or consist of an inorganic semiconductor, for instance, an elemental semiconductor such as silicon or germanium, an alloy semiconductor, such as II-VI, III-V, IV-IV or other forms of binary, tertiary or quaternary materials, or 2D materials, for example, such as graphene or molybdenum disulphide (MoS₂). The semiconductor layer may also comprise or consist of an organic semiconductor.

Although claims have been formulated in this application to particular combinations of features, it should be understood that the scope of the disclosure of the present invention also includes any novel features or any novel combination of features disclosed herein either explicitly or implicitly or any generalization thereof, whether or not it relates to the same invention as presently claimed in any claim and whether or not it mitigates any or all of the same technical problems as does the present invention. The applicants hereby give notice that new claims may be formulated to such features and/or combinations of such features during the prosecution of the present application or of any further application derived therefrom.

1. A semiconductor device (1), comprising:
a substrate (2);
a semiconductor structure (4) disposed on the substrate, having a principal surface (5), and comprising a semiconductor layer (10) running between first and second ends (12, 13); and
a metal gate (30) disposed on the principal surface of the semiconductor structure such that a Schottky junction (31) is formed between the metal gate and the semiconductor structure, wherein the metal gate is disposed over a section (19) of the semiconductor layer between the first and second ends of the semiconductor layer for forming a channel (18) in the semiconductor layer and controlling conduction of charge carriers between the first and second ends of the semiconductor layer.

2. The semiconductor device of claim 1, further comprising:
a first gate structure (33) disposed over the semiconductor structure for accumulating charge carriers (32) in the semiconductor layer between the first end (12) of the semiconductor layer and the section (19) of the semiconductor layer to form a first contact region (20) to the channel (18); and
a second gate structure (36) disposed over the semiconductor structure for accumulating charge carriers in the semiconductor layer between the section of the semiconductor layer and the second end (13) of the semiconductor layer to form a second contact region (21) to the channel.

3. A semiconductor device (1), comprising:
a substrate (2);
a semiconductor structure (4) disposed on the substrate, having a principal surface (5), and comprising a semiconductor layer (10) running between first and second ends (12, 13);
a first gate structure (33) disposed over the semiconductor structure for accumulating charge carriers (32) in the semiconductor layer between the first end of the semiconductor layer and the section of the semiconductor layer to form a first contact region (20) to a channel (18) formed or formable in a section (19) of the semiconductor layer between the first and second ends of the semiconductor layer; and
a second gate structure (36) disposed over the semiconductor structure for accumulating charge carriers in the semiconductor layer between the section of the semiconductor layer and the second end of the semiconductor layer to form a second contact region to the channel.

4. The semiconductor device of claim 3, further comprising:
a metal gate (30) disposed on the principal surface of the semiconductor structure such that a Schottky junction (31) is formed between the metal gate and the semiconductor structure, wherein the metal gate is disposed over a section (19) of the semiconductor layer (10) between the first and second ends (12, 13) of the semiconductor layer for forming the channel (18) in the semiconductor layer and controlling conduction of charge carriers between the first and second ends of the semiconductor layer.

5. The device of claim 1, wherein the semiconductor layer (10) comprises germanium.

6. The device of claim 1, wherein the semiconductor layer (10) is compressively-strained.

7. The device of claim 6, wherein lattice mismatch in the semiconductor layer (10) is between 0.01% and 2.5%.

8. The device of claim 1, wherein the semiconductor layer (10) is undoped.

9. The device of claim 1, the semiconductor structure comprises:
a buffer layer (6) which is graded; and
a cap layer (24) which provides the principal surface;
wherein the semiconductor layer is interposed between the buffer layer and the cap layer.

10. The device of claim 9, wherein:
the buffer layer (6) comprises Si₁₋ₓGeₓ, wherein x changes from x₁ to x₂,, and
the cap layer (24) comprises Si_{1-y}Ge_{y}.

11. The device of claim 9, wherein the semiconductor structure further comprises:
a relaxed layer (8) interposed between the buffer layer and the semiconductor layer.

12. The device of claim 11, wherein the relaxed layer (8) comprises Si_{1-z}Ge_{z}.

13. The device of claim 1, the semiconductor layer provides the principal surface.

14. The device of claim 1, wherein the metal gate (30) comprises titanium or tungsten.

15. The device of claim 2, wherein the first gate structure (33) comprises:
a gate dielectric layer (34); and
a gate electrode layer (35),
wherein the gate dielectric layer is interposed between the semiconductor structure (4) and the electrode layer.

16. The device of claim 2, wherein the second gate structure (36) comprises:
a gate dielectric layer (37); and
a gate electrode layer (38),
wherein the gate dielectric layer is interposed between the semiconductor structure and the electrode layer.

17. The device of claim 2, wherein the first and second gate structure (33) comprises:
a gate dielectric layer (34); and
a gate electrode layer (35),
wherein the gate dielectric layer is interposed between the semiconductor structure and the electrode layer.

18. The device of claim 1, wherein the substrate (2) comprises silicon.

19. A circuit comprising at least one device of claim 1.

20. The circuit of claim 19, wherein the circuit is an integrated circuit or a quantum information processing circuit.
